(19) United States
(12) Patent Application Publication
(10) Pub. No.: US 2023/0057869 A1
(43) Pub. Date: Feb. 23, 2023

(54) RESONANT FREQUENCY-BASED MAGNETIC SENSOR AT VEERING ZONE AND METHOD

(71) Applicant: KING ABDULLAH UNIVERSITY OF SCIENCE AND TECHNOLOGY, Thuwal (SA)

(72) Inventors: Nouha ALCHEIKH, Thuwal (SA); Sofiane BEN MBAREK, Thuwal (SA); Mohammad YOUNIS, Thuwal (SA)

(21) Appl. No.: 17/792,279

(22) PCT Filed: Dec. 21, 2020
(86) PCT No.: PCT/IB2020/062307

§ 371 Date: Jul. 12, 2022

Related U.S. Application Data
(60) Provisional application No. 62/960,311, filed on Jan. 13, 2020.

(51) Int. Cl. G01R 33/028; G01R 33/038; B81B 7/02

(52) U.S. Cl. CPC G01R 33/0286; G01R 33/0385; B81B 7/02

(57) ABSTRACT

A method for measuring a magnetic field with a micro-sensor system includes applying a direct current (I_{Th}) to a curved micro-beam to control a stiffness of the curved micro-beam; placing the micro-sensor system into an external magnetic field (B); selecting with a controller, based on an expected value of the external magnetic field (B), a given resonant frequency of the micro-beam; measuring with a resonant frequency tracking device the given resonant frequency of the micro-beam; and calculating in the controller the external magnetic field (B), based on (1) the measured resonant frequency, (2) the applied current (I_{Th}), and (3) calibration data stored in the controller. The calibration data is indicative of a dependency between a change of the selected resonant frequency and the external magnetic field.

### CROSS-REFERENCE TO RELATED APPLICATIONS

This application claims priority to U.S. Provisional Patent Application No. 62/960,311, filed on Jan. 13, 2020, entitled “HIGHLY SENSITIVE RESONANT MAGNETIC SENSOR,” the disclosure of which is incorporated herein by reference in its entirety.

### BACKGROUND

### Technical Field

Embodiments of the subject matter disclosed herein generally relate to a magnetic sensor and a method for measuring a magnetic field, and more particularly, to a beam-based magnetic sensor that is configured to exhibit the veering phenomenon and measure the magnetic field based on a shift in the resonant frequency.

### Discussion of the Background

Considerable research is being devoted to developing Microelectromechanical Systems (MEMS) magnetic sensors based on Lorentz-force resonant sensing. These sensors have a low-fabrication cost, high-resolution, high-sensitivity, compact size, and low-power consumption. MEMS magnetic sensors have been explored for various applications, such as biomedical, inertial navigation systems, electronic compasses, telecommunications, and non-destructive testing. Nowadays, some applications such as space satellites need inertial measurement units (IMUs), which integrate multiple sensors in one chip. MEMS Lorentz-force sensors have the advantage of being easy to integrate with other inertial sensors formed by accelerometers and gyroscopes.

Resonant Lorentz-force MEMS magnetic sensors generally rely on two classes of readout: amplitude modulation (AM) and frequency modulation (FM). In AM, the magnetic field is measured through the change in the amplitude of the resonator's motion. The amplitude of the motion is amplified by the quality factor of the resonator (Q), which increases the sensitivity of the sensor. However, the sensitivity of such a sensor is temperature dependent because the quality factor Q of the resonator is significantly affected by temperature.

The principle of the FM magnetic sensors is based on tracking the resonant frequency shift of the micro-structure that forms the magnetic sensor. Compared to the AM readout sensors, tracking the frequency shift yields a high-accuracy, high outstanding stability, high-sensitivity, low-power consumption, and immunity to noise. Different sensing techniques and designs have been used to detect the resonator's amplitude and frequency shifts, such as capacitive, piezoresistive, piezoelectric, and optical sensing techniques.

The inventors have demonstrated in previous works sensitive pressure and gas sensors based on the convection cooling of an electrothermally heated resonant micro-beam [1-3]. Previously reported FM magnetometers were realized by detecting the resonant frequency shift of the resonator due to axial loads created by the Lorentz-force [4-5]. However, the existing FM magnetometers are not having a high sensitivity.

Thus, a device with a high-sensitivity and a small size, which is also simple in fabrication, operation, and sensing scheme, would be highly desirable.

### BRIEF SUMMARY OF THE INVENTION

According to an embodiment, there is a method for measuring a magnetic field with a micro-sensor system. The method includes applying a direct current (I_{Th}) to a curved micro-beam to control a stiffness of the curved micro-beam, placing the micro-sensor system into an external magnetic field (B), selecting with a controller, based on an expected value of the external magnetic field (B), a given resonant frequency of the micro-beam, measuring with a resonant frequency tracking device the given resonant frequency of the micro-beam, and calculating in the controller the external magnetic field (B), based on (1) the measured resonant frequency, (2) the applied current (I_{Th}), and (3) calibration data stored in the controller. The calibration data is indicative of a dependency between a change of the selected resonant frequency and the external magnetic field.

According to another embodiment, there is a micro-sensor system for measuring an external magnetic field. The micro-sensor system includes a micro-beam that is clamped at each end to corresponding first and second pads, wherein the micro-beam is curved, a first voltage source configured to apply a direct current (I_{Th}) to the curved micro-beam to control a stiffness of the curved micro-beam, a controller configured to control the first voltage source, and based on an expected value of the external magnetic field, to select a given resonant frequency of the micro-beam to be monitored, and a resonant frequency tracking device configured to measure the given resonant frequency of the micro-beam. The controller calculates the external magnetic field (B), based on (1) the measured resonant frequency, (2) the applied current (I_{Th}), and (3) calibration data stored in the controller. The calibration data is indicative of a dependency between a change of the given resonant frequency and the external magnetic field.

According to still another embodiment, there is a method of manufacturing a micro-sensor system that measures an external magnetic field. The method includes selecting geometrical characteristics of a micro-beam so that the micro-beam exhibits a veering zone, attaching both ends of the micro-beam to corresponding pads so that the micro-beam is curved, providing a first voltage source to supply a current to the micro-beam to control a stiffness of the micro-beam, providing a controller for controlling the first voltage source and selecting a given resonance frequency, providing a second voltage source for driving a actuating electrode with white noise, providing a resonant frequency tracking device for measuring a resonant frequency of the micro-beam, and loading calibration data into the controller. The calibration data is indicative of a dependency between a change of the given resonant frequency and the external magnetic field.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a curved micro-beam that is configured to measure an external magnetic field;

FIG. 2 is a schematic diagram of a micro-sensor system that is configured to measure an external magnetic field;

FIG. 3 illustrates the first and third resonant frequencies of the micro-beam for various electrical currents applied to the micro-beam;

FIG. 4A illustrates the first resonant frequency of the micro-beam when placed in various external magnetic fields, and FIG. 4B illustrates the third resonant frequency of the micro-beam when placed in various external magnetic fields;

FIG. 5A illustrates the normalized frequency shift versus the applied current for the first resonant frequency, and FIG. 5B illustrates the normalized frequency shift versus the applied current for the third resonant frequency;

FIG. 6 illustrates the normalized frequency shift versus the input magnetic field for the first resonance frequency;

FIG. 7A illustrates the sensitivity of the micro-beam versus the applied current for the first resonance frequency, and FIG. 7B illustrates the sensitivity of the micro-beam versus the applied current for the third resonance frequency;

FIG. 8 illustrates the mid-point displacement of the micro-beam versus the applied current for various external magnetic fields;

FIG. 9A illustrates the frequency variation of the micro-beam versus the bias current for various magnetic fields, and FIG. 9B illustrates the normalized change in the resonance frequency of the micro-beam for a same magnetic field, at different time instances;

FIG. 10 illustrates the sensitivity of the micro-sensor illustrated above versus traditional magnetic sensors;

FIG. 11A illustrates the simulated frequency variation of the micro-beam versus the applied current for the first resonance frequency, FIG. 11B illustrates the simulated frequency variation of the micro-beam versus the applied current for the third resonance frequency, and FIG. 11C illustrates the simulated difference between the first and third resonance frequencies of the micro-beam versus the applied current;

FIG. 12A illustrates measured and simulated frequency differences between the first and third resonance frequencies versus the applied current, for certain dimensions of the micro-beam, and FIG. 12B illustrates the normalized frequency change of the micro-beam versus the applied magnetic field for the first resonance frequency;

FIG. 13A illustrates simulated frequency variations of the first and third resonance frequencies of the micro-beam versus the applied current, for different initial rises, FIG. 13B illustrates the variation of the sensitivity of the micro-beam for various initial rises for the first resonant frequency, and FIG. 13C illustrates the variation of the sensitivity of the micro-beam for various initial rises for the third resonant frequency;

FIG. 14A illustrates simulated frequency variations of the first and third resonance frequencies of the micro-beam versus the applied current, for different lengths of the micro-beam, FIG. 14B illustrates the variation of the sensitivity of the micro-beam for various lengths for the first resonant frequency, and FIG. 14C illustrates the variation of the sensitivity of the micro-beam for various lengths for the third resonant frequency;

FIG. 15A illustrates simulated frequency variations of the first and third resonance frequencies of the micro-beam versus the applied current, for various thicknesses of the micro-beam, FIG. 15B illustrates the variation of the sensitivity of the micro-beam for various thicknesses for the first resonant frequency, and FIG. 15C illustrates the variation of the sensitivity of the micro-beam for various thicknesses for the third resonant frequency;

FIG. 16 is a flow chart of a method for manufacturing the micro-sensor discussed above; and

FIG. 17 is a flow chart of a method for measuring an external magnetic field with the micro-sensor discussed above.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a magnetic micro-sensor operating in air at atmospheric pressure. However, the embodiments to be discussed next are not limited to such a configuration, but may be applied to other situations, for example, under an increased or decreased pressure or in a medium that is different from air.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a micro-sensor is configured to detect a bi-directional magnetic field by measuring the frequency shift of the in-plane motion of a curved clamped-clamped micro-beam. In one application, the micro-sensor exhibits the veering phenomenon between its first two symmetric vibration modes. The magnetic micro-sensor is based on detecting the resonance frequency shift of an electrothermally heated, initially curved, micro-beam, that is selected to exhibit the veering phenomenon (i.e., avoid crossing of two consecutive vibration modes) between the first and the third vibration modes or resonant frequencies. Finite element method (FEM) and experimental results, as discussed later, show that the proposed micro-sensor exhibits a high-sensitivity around the veering zone for the third mode. When operated in the first mode, the micro-sensor shows a measured sensitivity (S) of 0.16/T, which is very high compared to the state of the art. At the veering phenomenon, the third mode is very sensitive to perturbations, and hence the micro-sensor becomes even more sensitive (S=0.32/T), making it promising for various magnetic field applications. The new magnetic micro-sensor shows a minimum detectable magnetic field of 20 mT at atmospheric pressure. This offers more shifting in frequency, and thus a higher-sensitivity than the existing magnetic sensors.

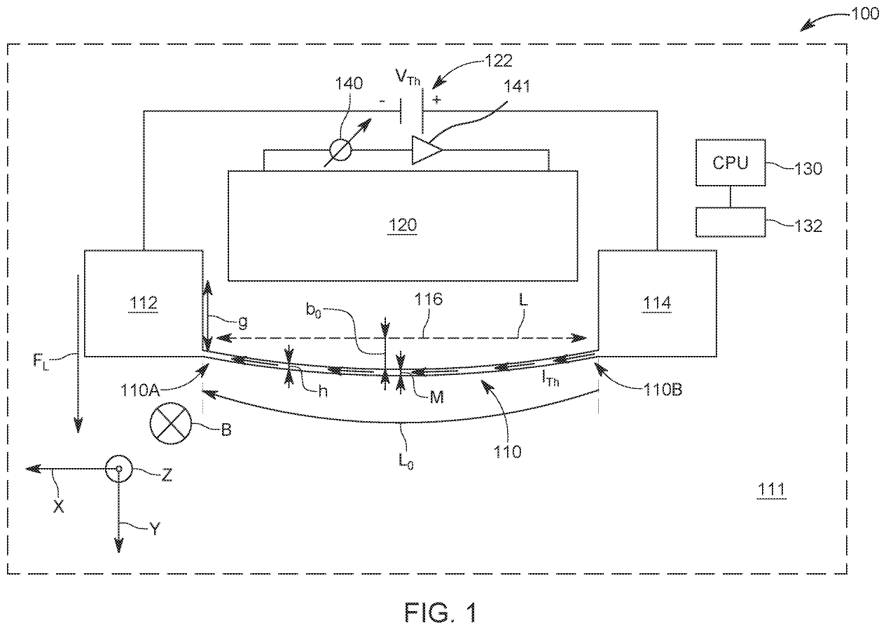

A schematic of an embodiment of the magnetic micro-sensor is illustrated in FIG. 1. Note that the term “micro” is used in this application to indicate a size smaller than a couple of mm, for example, 10 or even 1 mm. The magnetic micro-sensor 100 includes a micro-beam 110 having both ends 110A and 110B fixedly attached to two pads 112 and 114. An actual length L₀ of the curved micro-beam is less than 1 cm. in one application, the actual length L₀ is smaller than 1 mm. The micro-beam 110 may be fabricated from a highly-doped silicon layer of a silicon-on-insulator (SOI) wafer. The micro-beam 110 is installed so that a distance L (length of the straight micro-beam) between the pads 112 and 114 is smaller than the actual length L₀ of the micro-beam, so that the micro-beam is curved, as shown in the figure. This shape is achieved without applying any electrical, magnetic, thermal or optical energy. In other words, the micro-sensor 100 has the micro-beam 110 curved, when not activated, with no applied electrical current, magnetic field or heat. A length L of the micro-beam may be about 800 μm, a width b (along the Z axis) may be about 25 μm, a thickness h may be about 1.9 μm, and an initial rise b₀ (i.e., a distance between its midpoint A to its straight beam level 116) may be about 2.4 μm. A transduction gap g between an actuating electrode 120 and the first clamped end 110A of the micro-beam 110 is 10 μm. These parameters are selected depending on the intensity of the magnetic field to be measured, and the desired sensitivity with which the measurements need to be taken. Other dimensions may be used as long as they conform with the veering phenomenon, i.e., these parameters are selected to obtain a micro-beam that exhibits the veering phenomenon. If the micro-beam does not exhibit the veering phenomenon, a magnetic micro-sensor based on such micro-beam would not achieve the advantages of the micro-sensor 100 discussed herein.

The actuating electrode 120 is connected to a voltage source 140 (e.g., a Micro System Analyzer MSA-500 from Polytec) through an amplifier 141. The amplifier 141 is configured to receive a DC bias VDC and AC harmonic voltage from the voltage source 140, to amplify them, and to apply them to the micro-beam 110 to electrostatically actuate the micro-beam. In one embodiment, the amplifier 141 is configured to amplify a white noise received from the voltage source 140, i.e., a voltage that changes randomly and has a small amplitude. This white noise received from the voltage source 140 is applied between the actuating electrode 120 and the micro-beam 110 to make the micro-beam oscillate. A controller 130, which may include a processor and a memory, may be used to control the voltage source, and the amplifier 141, to apply the desired AC and DC currents to drive the micro-beam 110. The connections between the controller 130 and the various elements of the sensor 100 may be wired or wireless or mixed. A power supply 132 (e.g., a battery if the sensor is portable, otherwise it can be a traditional power outlet) may be provided to supply the necessary energy for the controller 130, the voltage source 140, the amplifier 141, and other elements of the sensor as discussed later. Note that the amplifier 141 is optional and the source 140 may be directly connected to the driving electrode.

The two pads 112 and 114 may be attached to a substrate 111, and they are fixed. Another voltage source 122 is applying a DC current to the pads 112 and 114. The current I_{Th} generated through the micro-beam 110 heats the beam, and makes it increase its actual length L₀. However, because the two ends 110A and 110B of the micro-beam 110 are fixed to the pads 112 and 114, and the length L between the pads is fixed and smaller than L₀, the micro-beam bends, thus increasing its curvature. The voltage source 122 is also controlled by the controller 130. In this way, the controller 130 can adjust the length of the micro-beam, by sending an appropriate current into the micro-beam and heating it. The micro-beam 110 is not attached to the substrate, except for its ends, and thus, it can move relative to the substrate 111, to change its curvature.

When a magnetic field B is present (shown in the figure extending along the Z axis) and a DC current I_{Th} flows through the micro-beam, a Lorentz-force F_{L} is generated, normal to the curved micro-beam along the y-axis. This force is responsible for changing the curvature of the beam. This force alters the stiffness of the beam 110, by increasing or decreasing the beam's curvature, depending on the direction of the magnetic B, and results in an upward or downward shift in the resonant frequency of the beam. As discussed later, the dependency between the external magnetic field B and the shift in the resonance frequency of the beam can be measured and used to estimate the external magnetic field.

The sensitivity S (1/T) of the micro-sensor 100 to the magnetic field B is defined as the normalized frequency shift per unit of magnetic field density, and can be expressed as:

$$S = \frac{\partial ( Δ f / {f}_{0} )}{\partial B} = \frac{{I}_{T h} L}{2 k} , \qquad ( 1 )$$

where k and f₀ are the stiffness and the resonance frequency (at B=0 T) of the micro-beam, respectively, and Δf is the frequency shift, which is defined as (f−f₀), where f is the resonance frequency at a given external B that is not zero.

As can be seen from equation (1), the sensitivity S of the micro-sensor is related to the ratio between the Lorentz-force and the spring constant k, which means that the sensitivity S can be enhanced by increasing the Lorentz-force F_{L} or by decreasing the stiffness k. On the other hand, the sensitivity S can be further optimized by increasing the current I_{Th} and taking advantage of a more compliant micro-resonator, such as longer beam, smaller initial rise, thinner beam, and a more elastic material that makes up the beam.

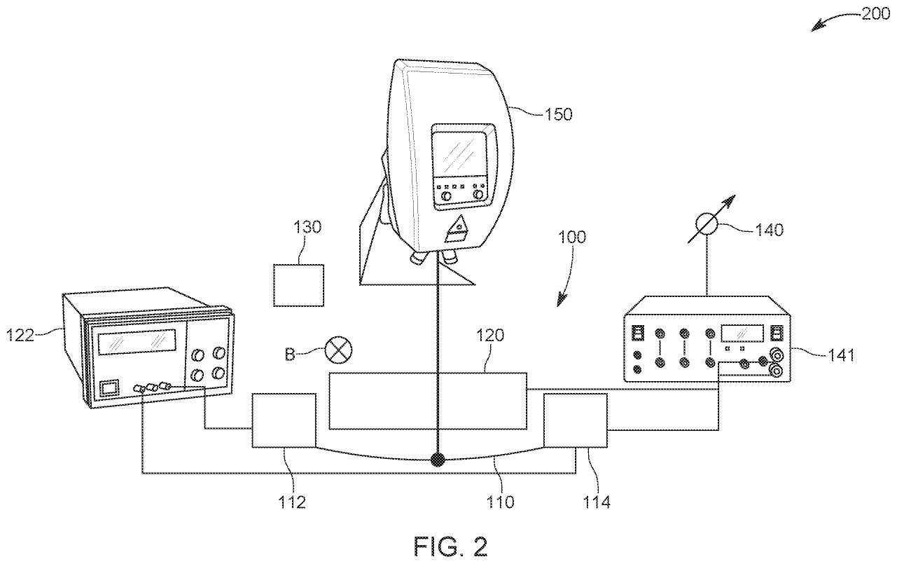

The resonant frequency's variation for the micro-beam 110 can be tracked using a laser Doppler vibrometer 150 when actuating the beam with the white noise signal applied by the actuating electrode 120, as illustrated in FIG. 2. FIG. 2 shows a magnetic sensor system 200 that includes the magnetic micro-sensor 100 (note that some elements of the sensor 100 shown in FIG. 1 are omitted in this figure for simplicity), the controller 130, the voltage sources 122 and 140, the amplifier 141, and the resonant frequency tracking device 150. The actuating electrode 120 of the resonator is electrically connected to the DC and AC voltage source 122 while the micro-beam 110 is thermally controlled by the current I_{Th} amplified by the amplifier 140, which is originally generated by the voltage source 140. In one application, the voltage source 140 is controlled by the controller 130 to apply the white noise to the actuating electrode 120, and implicitly to the micro-beam 110. All measurements and tests in this disclosure are conducted at ambient pressure. Alternatively, other frequency tracking devices that are used in the industry may be used for measuring the resonant frequency of the micro-beam 110.

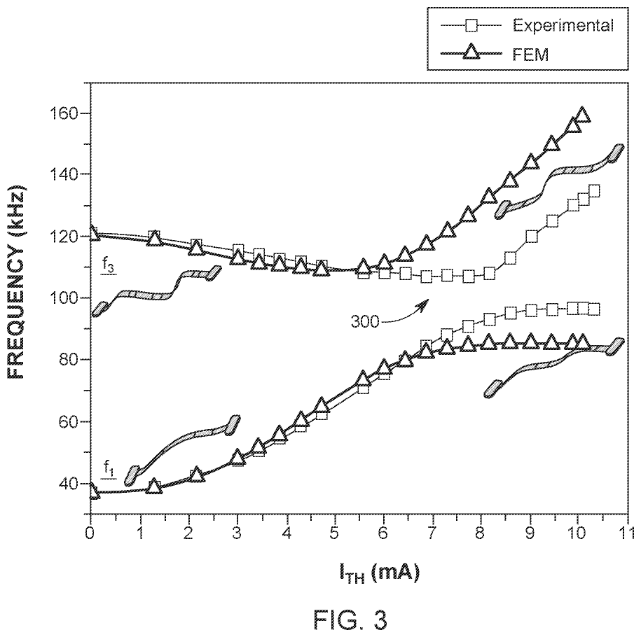

At zero magnetic field B, upon charging the micro-beam with the current I_{Th}, the first resonant frequency f₁, as shown in FIG. 3, increases up to twice its original value due to the continuous increase in the beam 110's curvature (stiffness). The third resonant frequency f₃, also shown in FIG. 3, decreases until getting very close to the first resonant frequency f₁ (see veering zone 300) before they veer away from each other, with a high curvature. Thus, in this embodiment, the curved micro-beam 110 is designed (i.e., its sizes are selected in a certain way, as discussed later) to exhibit veering [6]. Also shown in FIG. 3 are simulations results for a specific micro-beam 110 having the dimensions h=1.5 μm and b₀=2.3 μm. It is noted that the simulation results show a similar behavior to the experimental data until reaching the veering zone 300. The simulations are obtained from a FEM model using a commercial software program. The discrepancy between the experiments and FEM results around the veering zone can be explained by the fabrication imperfections, such as non-uniform thickness and width along the beam.

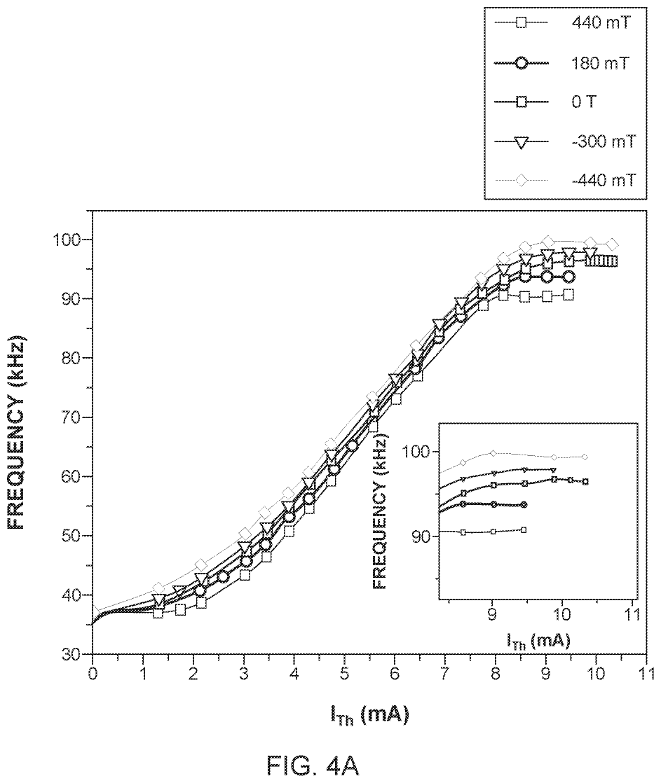

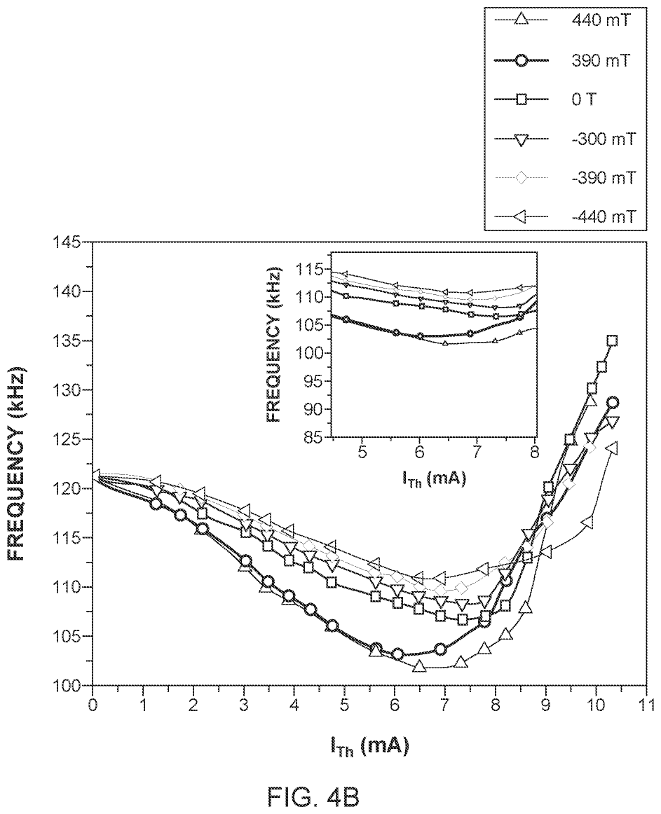

Various tests were performed with the sensor system 200 to detect magnetic fields and also to evaluate the sensitivity of the sensor 100. In a first test, the frequency response of both the first and third modes (f₁ and f₃) were measured, with the I_{Th} current on and a magnetic field applied to the beam 110. FIGS. 4A and 4B illustrate the obtained results for positive and negative DC magnetic fields consecutively applied to the beam. To generate the DC magnetic field along the z-axis (see FIG. 1), a Neodymium permanent magnet was placed above the sensor 100 at various distances. Under the same value of +B (+z-axis), the frequency responses of the micro-beam 110 was measured with the resonant frequency tracking device 150, while changing the current I_{Th} generated by the voltage source 122. The same process was repeated by changing the direction of the magnetic field −B (to be along the −z-axis). It is noted that the plural curves shown in FIG. 4A for the first resonant frequency are substantially identical at different magnetic fields, while the plural curves shown in FIG. 4B for the third resonant frequency slightly diverge from each other for a given range of the applied current I_{Th}.

At the same current I_{Th} and for different values of the positive magnetic field+B=0 mT, 180 mT and 440 mT, the Lorentz-force (−F along the −y-axis) causes a decrease in the initial curvature and beam stiffness, and thus it causes a negative frequency shift (−Δf). Reversing the direction of the applied magnetic field −B reverses the direction of the Lorentz-force (+F), which causes an increase in the initial curvature, and thus increases the resonant frequency of the resonator (+Δf). The frequency shift (Δf) is defined in this embodiment to be (f−f₀), where f₀ and f are the frequency of the micro-beam at 0 T magnetic field and during the measurement with a given magnetic field, respectively. As shown in FIG. 4A, a maximum frequency shift (±Δf) is obtained after the veering phenomenon for f₁ (I_{Th}=9.35 mA) and as shown in FIG. 4B, the maximum frequency shift is obtained at the veering phenomenon for f₃ (I_{Th}=7.7 mA).

As one target of the new magnetic micro-sensor 100 is to have a very high sensitivity for the external magnetic field, a relationship between the sensitivity S and the veering phenomenon is now investigated. For this purpose, the first two symmetric modes (i.e., first and third resonant frequencies) of the curved beam 110 are modeled as two springs with stiffness k₁ for the first resonant frequency f₁ and stiffness k₂ for the second resonant frequency f₃. Each spring is considered to have a mass m, and both masses are connected (coupled) to each other by a spring having the stiffness kc. The value of kc determines the veering zone and the closeness between the resonant frequencies f₃ and f₁. For k₂/k₁=1 and for a small kc, the resonance frequencies f₁ and f₃ are very close. For I_{Th} at the veering zone and for different values of +B, the Lorentz-force causes a decrease in the micro-beam's stiffness (enhances more the coupling) and its frequencies get more closer around veering. As it is well-known, the eigenvalues/resonance frequencies become very sensitive to variations in stiffness (the slope of the veering curves exhibits sharp change). Thus, for positive magnetic fields +B, the Lorentz-force causes a high shift in the frequency shift Δf. On the other hand, for negative magnetic fields −B, the frequencies get farther apart, which results in a small frequency shift Δf. It can be seen from equation (1), that the sensitivity is not only proportional to Δf, but is also inversely proportional to f₀. This is shown in FIG. 3, where the first resonance frequency f₁ increases while increasing the applied current I_{Th} and then slows down, and almost flattens, as it gets close and passes the third resonance frequency. Hence, the quantity Δf/f₀ of the first mode is strongly dependent on the input current I_{Th}. On the contrary, the third resonance frequency f₃ decreases and gets closer to f₁ at a critical applied current I_{Th} (veering zone) and then starts to increase. Hence, the quantity Δf/f₀ for the third mode f₃ is maximum at the veering region (because f₃−f₀ is minimum) and thus it yields the highest sensitivity at this input current.

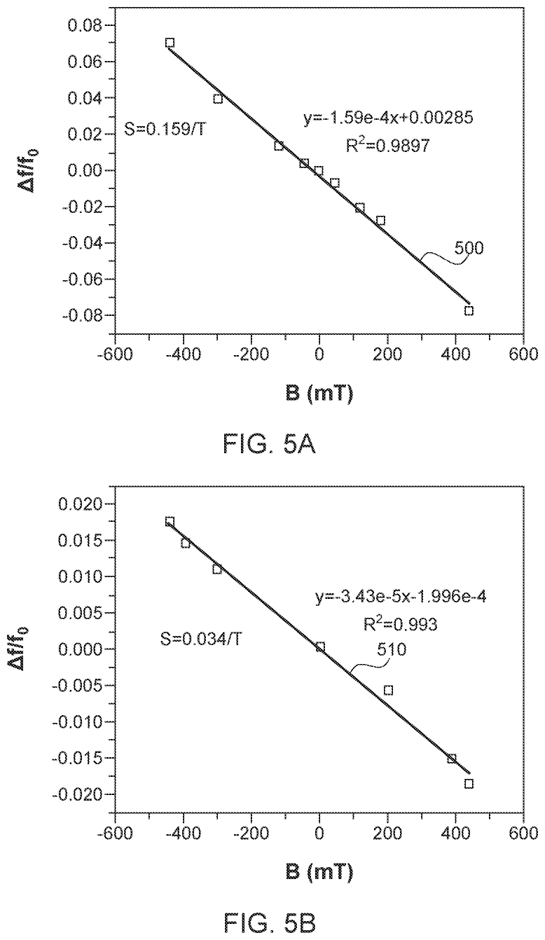

The measured normalized frequency shift (Δf/f₀) against the magnetic field B at a bias current of 2.15 mA, away from the veering zone, for both the first and third modes, is shown in FIGS. 5A and 5B. According to equation (1), the slope of the linear fit defines the micro-beam's sensitivity S. As shown in FIG. 5A, the sensitivity S (the slope of the linear fit 500) at the first mode is 0.159/T, while FIG. 5B shows that the sensitivity S (the slope of the linear fit 510 for the third mode is 0.034/T). The squares in these two figures indicate the experimental measurements.

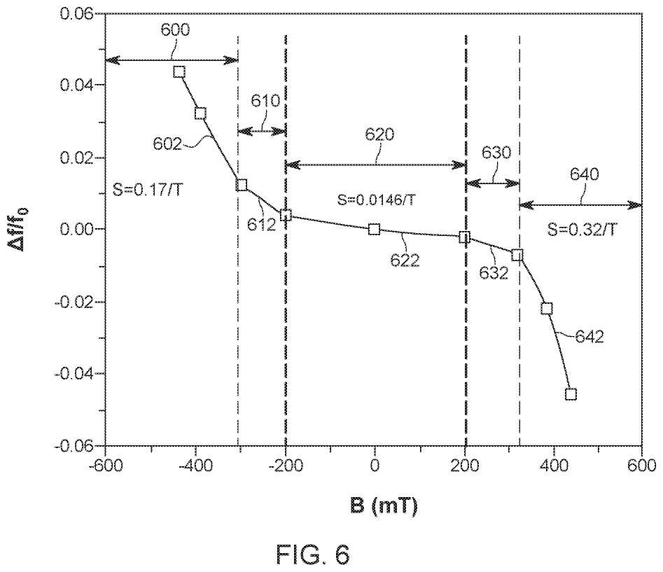

In this regard, FIG. 6 shows the experimental data of the normalized frequency (Δf/f₀) as it varies with B as the applied current I_{Th} is fixed at 7.7 mA (around the veering zone) for the third mode. The results in the figure show plural nonlinear trends. Thus, the results are divided into five linear zones 600 to 640. For each zone, the sensitivity S is calculated using the slope of the corresponding linear fit 602, 612, 622, 632, and 642. As shown in FIG. 6, the last linear regime 640 for the positive magnetic field (+B), and for very large magnetic field strengths, shows the highest sensitivity (0.32/T) while this value reduces to 0.17/T for the opposite magnetic field (−B) for the first linear zone 610. This means, that the magnetic micro-sensor 100 can be configured (within the controller 130) to measure the magnetic field with different sensitivities, depending on the sign and amplitude of the external magnetic field.

In one application, the controller 130 may be pre-programmed, before the sensor is deployed for making measurements, for a given current I_{Th}, to use the third resonance frequency for achieving a high sensitivity, and to use the first resonance frequency if lower sensitivities are acceptable. In other words, the user of the sensor system 200 can input, before measuring the magnetic field, what kind of sensitivity is required for the measurement, the controller 130 selects, based on the input sensitivity, whether to use the first resonant frequency, or the third resonant frequency, and then applies a corresponding current I_{Th}, for adjusting the stiffness of the beam 110. Then, the sensor is deployed in the magnetic field to be measured, the generated Lorentz-force further deforms the beam, the frequency shift is measured by the resonant frequency tracking device 150, the controller 130 estimates the normalized frequency change Δf/f₀, and then, the controller reads the corresponding magnetic field B from the graph shown in FIG. 6, if the third resonant frequency is used. If the first resonance frequency is used, then a similar graph is a priori determined and later used to map the measured normalized change in the frequency to the corresponding magnetic field. The data shown in FIG. 6 is stored in a memory associated with the controller 130 prior to the sensor being deployed in the field for actual measurements. Other graphs similar to the one shown in FIG. 6 may be generated for various currents I_{Th} or other frequencies and all these graphs may be stored in the memory of the controller. Thus, the controller 130 can also select what current I_{Th} to apply to the beam 110 prior to measuring the magnetic field.

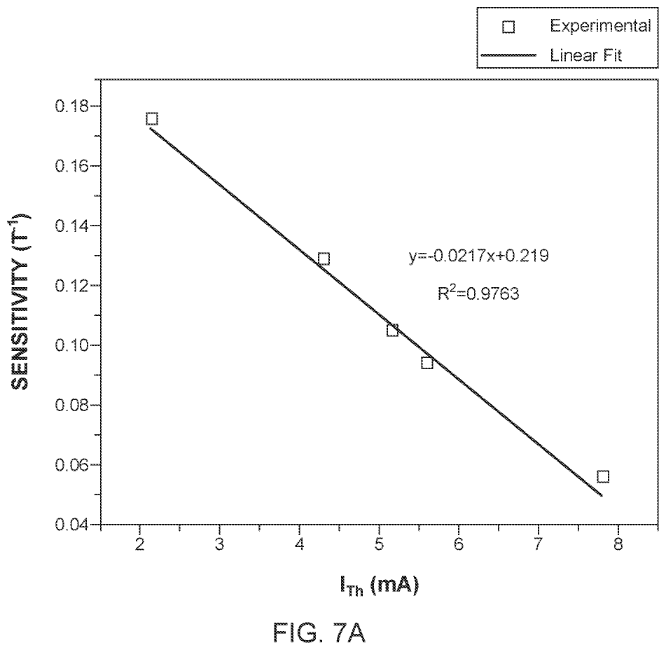

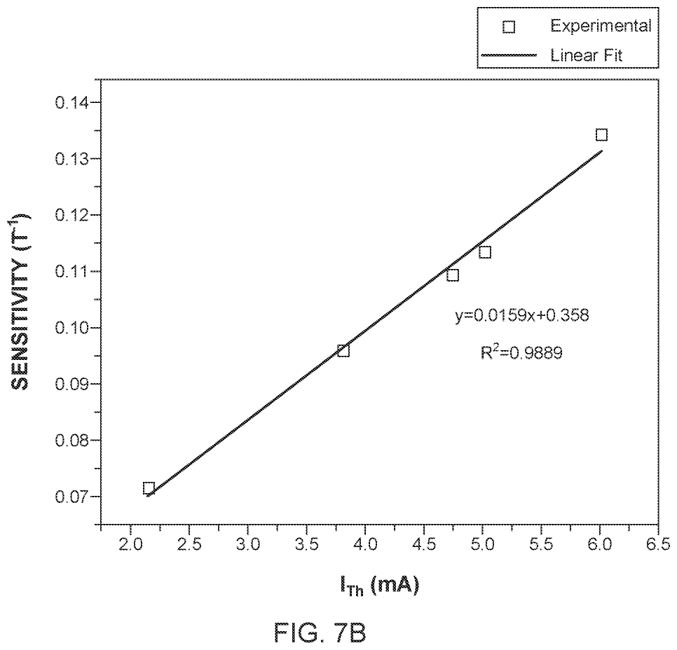

Next, the results of the sensitivity versus the bias current are investigated. FIG. 7A plots the sensitivity of the first mode and FIG. 7B plots the sensitivity of the third mode for the positive direction of the magnetic field (+B) as the current I_{Th} is increasing. It can be seen from FIG. 7A that the sensitivity S of the first mode decreases while from FIG. 7B it can be seen that the sensitivity S for the third mode increases with an increase in the applied current I_{Th}. Increasing the current from 2 mA to 6 mA (before the veering zone) in FIG. 7B almost doubles the sensitivity S for the third mode. On the other hand, the results in FIG. 7A show that there is a significant reduction in the sensitivity S when increasing the current for the first mode (almost 125%). These observations can be explained by the fact that the first resonance frequency increases and doubles while increasing the current I_{Th} while the third resonance frequency decreases slightly with increasing the current I_{Th}, as already illustrated in FIG. 3. However, the sensitivity S appears to be very dependent on the input current.

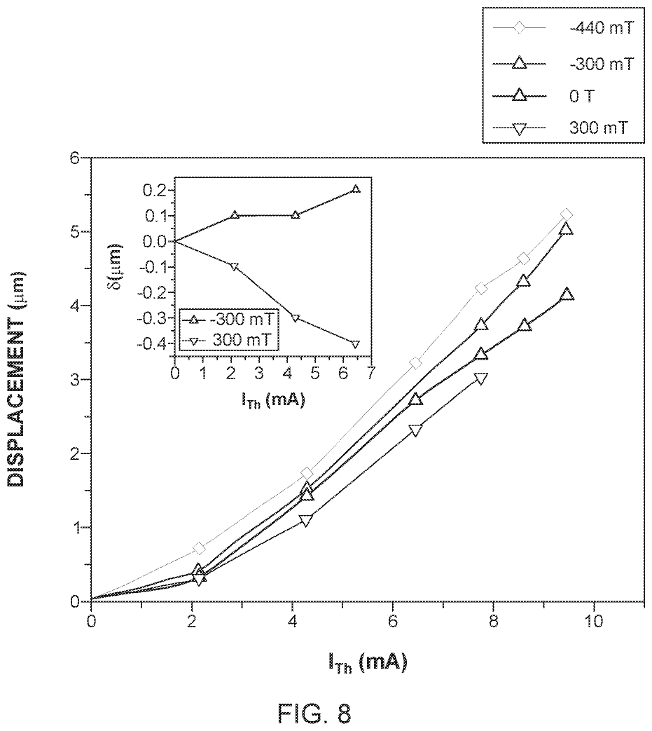

According to the results shown above, the sensitivity of the magnetic sensor 100 can be improved by a stronger activation of the veering phenomenon between f₁ and f₃. This can be achieved by choosing the geometrical parameters and the initial shape of the micro-beam 110 and using a material with a lower thermal conductivity and higher electrical conductivity [2, 3, 4, 6]. In this regard, FIG. 8 shows the measured static mid-beam deflection of the curved micro-beam 110 versus the applied current I_{Th}. The figure shows that for a fixed magnetic field+B and applied current I_{Th}, the micro-beam's displacement is lower than the displacement with the zero magnetic field. However, the micro-beam's displacement for a fixed magnetic field −B becomes higher than the displacement with zero magnetic field. These results agree with the previous frequency variation results, which highlight the effect of the direction of the Lorentz-force on changing the curvature of the micro-beam. Also, FIG. 8 shows that for a constant value of the current, the positive magnetic field (+B) results in a bigger displacement shift's absolute value when compared to that of the same magnetic field, but with an opposite direction (−B). The inset of FIG. 8 shows the displacement shift δ versus the bias current for two opposite directions of the magnetic field (±300 mT). The displacement shift β is defined as the difference between the mid beam displacement at 0 mT magnetic field and during the measurement for a fixed current with a given magnetic field. It can thus be seen that at the same current I_{Th}=6.5 mA, the displacement β for a magnetic field of +300 mT is 0.4 μm, and for −300 mT is 0.2 μm. These results are expected because the curved beam 110 tends to have a higher resistance to lateral forces that increase its curvature.

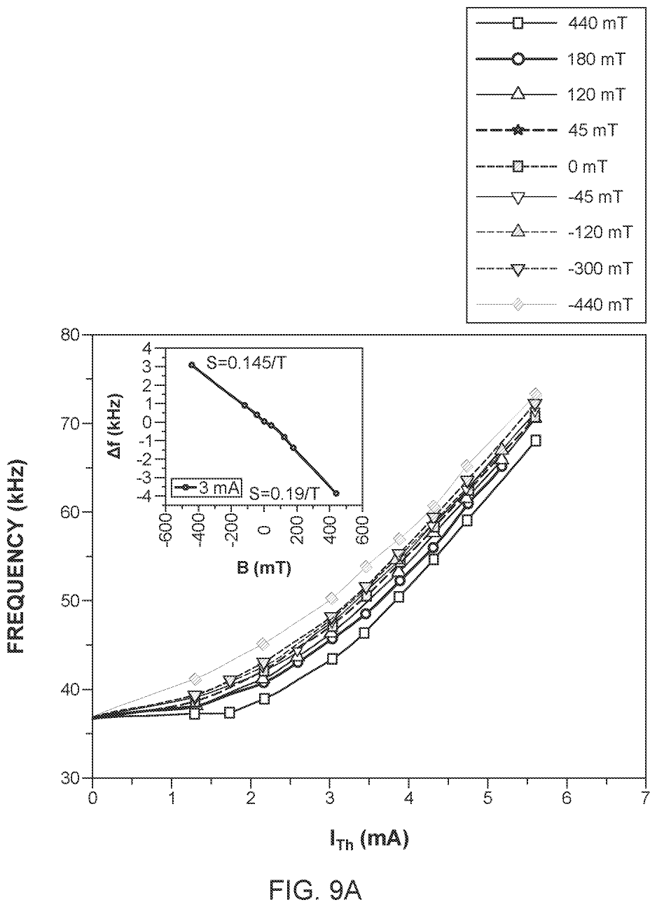

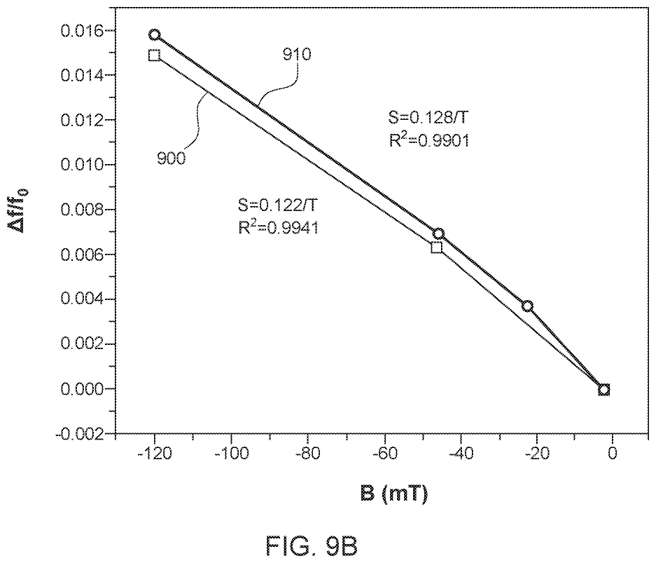

In addition to having a high sensitivity, the magnetic micro-sensor 100 also exhibits a low power consumption and a good resolution. At a current of I_{Th}=3 mA, the magnetic sensor has a power consumption around 2 mW due to the electrothermal actuation. In addition to the power used for electrothermal actuation, the magnetic sensor also uses power for the detection of the resonance frequency, which can be low when using capacitive methods. As shown in FIG. 9A, the frequency responses of the sensor can be measured for a wide range of magnetic field strengths, for example, in the range of ±45 mT. However, the sensor system 200 can sense a lower magnetic field, in the range of ±20 mT, and thus its lowest detectable magnetic field is in the range of ±20 mT at atmospheric pressure, as shown in FIG. 9B. Placing the sensor 100 in vacuum conditions in a sealed package can results in a sharper quality factor, lower noise, and hence leads to even lower detectable magnetic field and more optimized performance of the micro-sensor 100. The inset of FIG. 9A shows the measured frequency shift (Δf) versus the magnetic field B for a constant current of 3 mA. After the linear fitting of a wide range of magnetic fields B between −440 mT to 0, the micro-sensor 100 shows a high linearity. Also, the sensor exhibited excellent repeatability of the sensitivity over time, as shown by curves 900 and 910 in FIG. 9B, which were taken two months apart.

In addition to the high-sensitivity, the low-noise is one of the performance requirements of a magnetic sensor. Hence, a frequency noise analysis has been performed for the new magnetic micro-sensor 100 by analyzing the Allan deviation. Prior work in the art analyzed the Allan deviation of an in-plane curved micro-beam, similar to the one used in this work, in an open-loop configuration, at a constant AC voltage (0.22 V RMS). The results from that work show that at a low integration time, the noise is dominated by white noise while at a higher integration time, the fluctuation is dominated by the thermal drift. The maximum Allan deviation was found to be around 7×10⁻⁵.

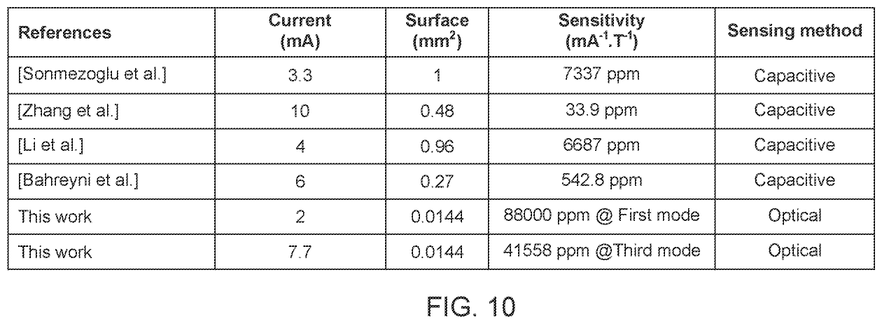

In this regard, the table in FIG. 10 shows a comparison for the performance of the present sensor 100 with other existing sensors. It is noted that the current sensor's sensitivity depends on the direction of B and it is also a function of the applied current I_{Th}. Hence, this requires a compromise between choosing the current that yields a high sensitivity versus minimizing the current for low power consumption. The results in FIG. 10 indicate that the micro-sensor 100 uses a smaller current, has a smaller surface area, and a much higher sensitivity than the existing sensors.

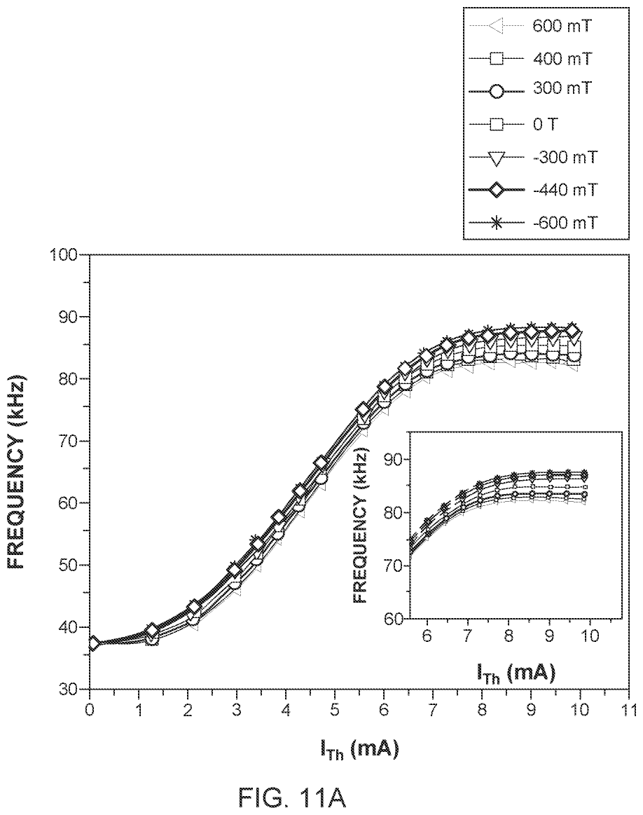

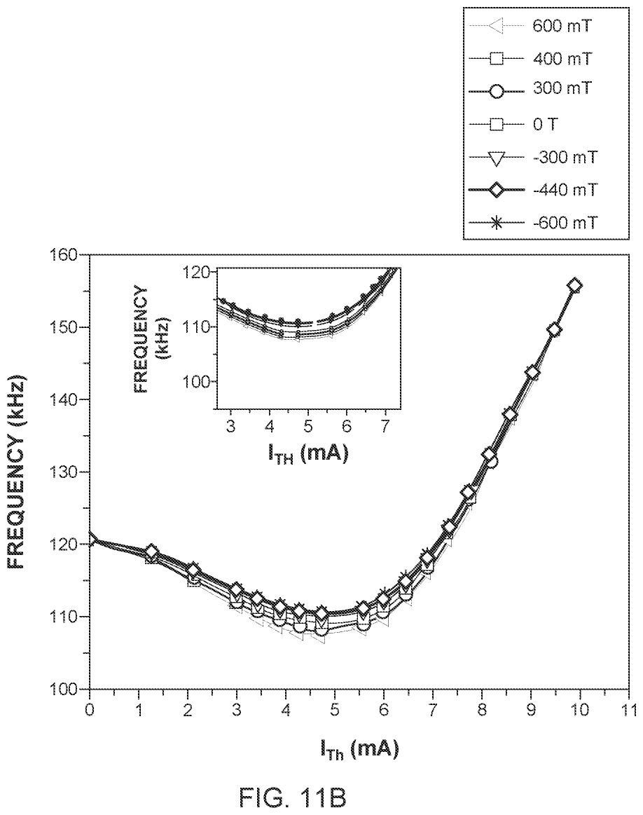

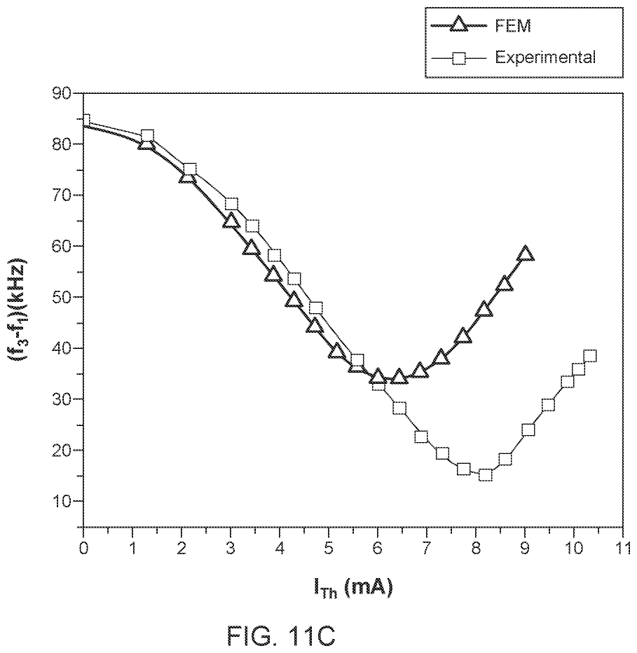

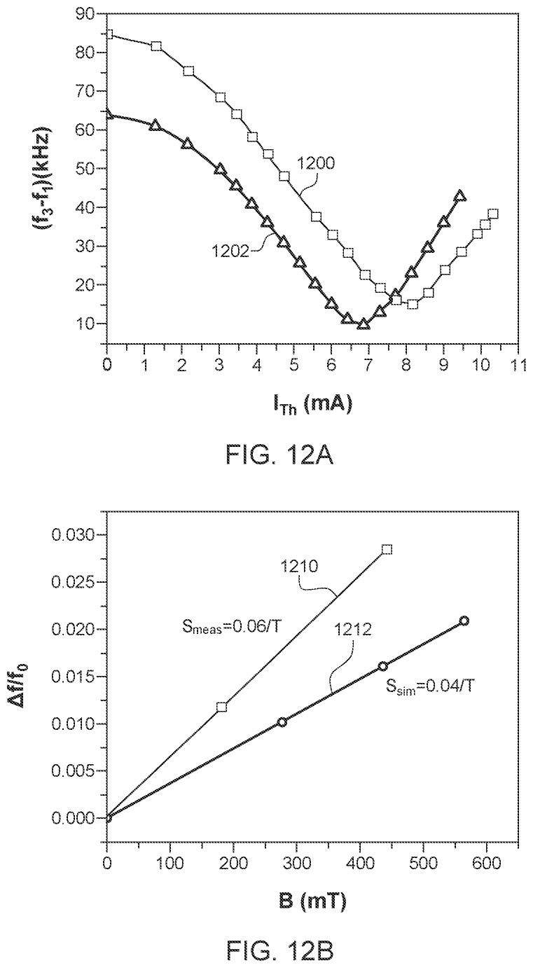

To confirm the high performance of the micro-sensor 100, FEM simulations of the sensor were performed as now discussed. A 3D multi-physics FEM using the software COMSOL was conducted by coupling the Joule Heating and Thermal Expansion module with the Magnetic Fields module. To obtain the total force acting on the micro-beam 110 along the y-axis, a numerical integration method of the Lorentz force formula was used as F=J×B, where J is the current density calculated from the Joule Heating module and B is the magnetic flux density in the z-axis. It is noted that the device's sensitivity is dependent on its geometry, which has a strong effect on the veering zone. FIGS. 11A and 11B show the simulated frequency response of both the first and third modes (f₁ and f₃) with the current I_{Th} and under the magnetic field (±B) for a beam with the geometrical parameters of h=1.5 μm and b₀=2.3 μm. FIG. 11C shows the variation of the resonance frequency difference (f₃−f₁) of the micro-beam while varying the current I_{Th}. It can be seen from FIG. 11C that the FEM results agree well with the experimental data (see FIGS. 3 to 4B) until arriving at the critical current I_{Th}≈5 mA (veering zone), after which, as the input current further increases, the deviation between the two resonance frequencies increases. This can be explained by the fabrication imperfections, such as their geometry, axial stress, curvature, and material properties. However, the discrepancy between the experimental data and FEM around and after the veering zone leads to a mismatch on their sensitivities. For another comparison around the veering zone, a FEM simulation has been conducted for a micro-beam with h=1.5 μm and b₀=4 μm. As shown in FIG. 12A, a small deviation is found in the frequency difference and input current around the veering zone for the experimental curve 1200 and the simulated curve 1202. FIG. 12B shows a comparison of the normalized frequency shift as a function of the input magnetic field, for the sensitivity for the first resonance frequency. As seen in FIG. 12B, the sensor response of both the experimental 1210 and simulation 1212 results is linear. It is noticed that the FEM simulation over-predicts the sensitivity by A % of 33% due to the imperfection in the geometrical dimensions. The percent deviation is calculated as follows: A %=((Sₘₑₐₛ−Sₛᵢₘ)/Sₘₑₐₛ)×100.

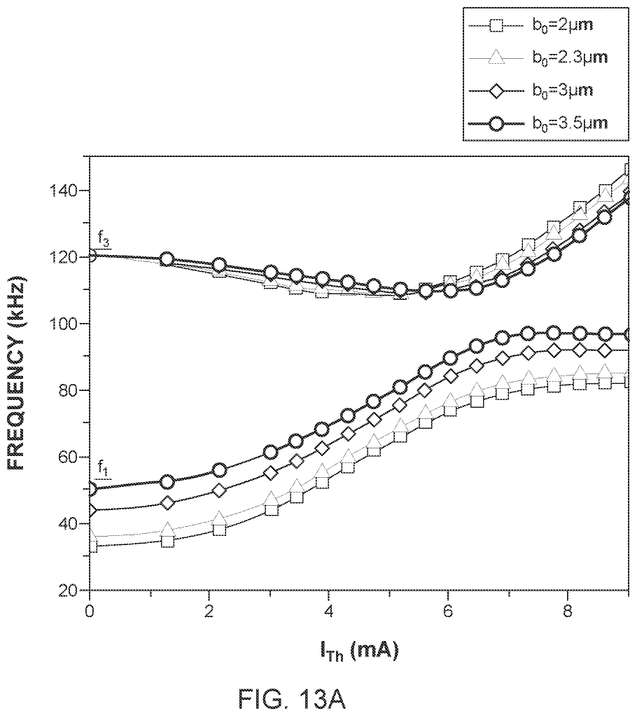

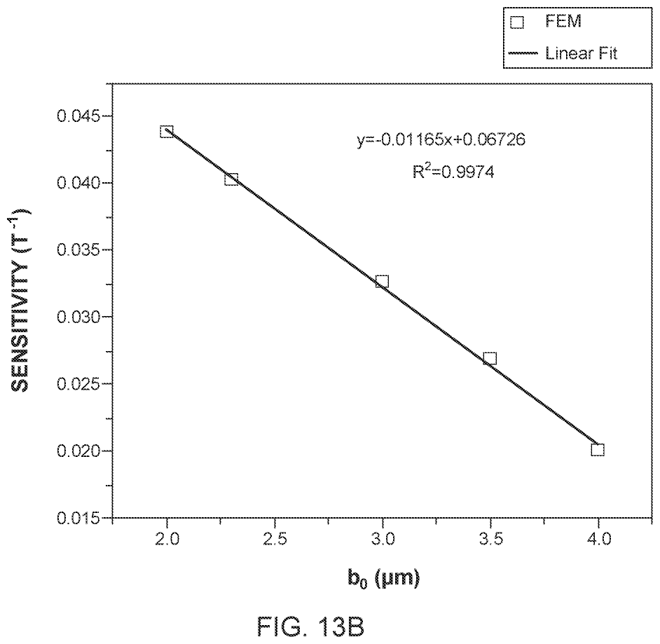

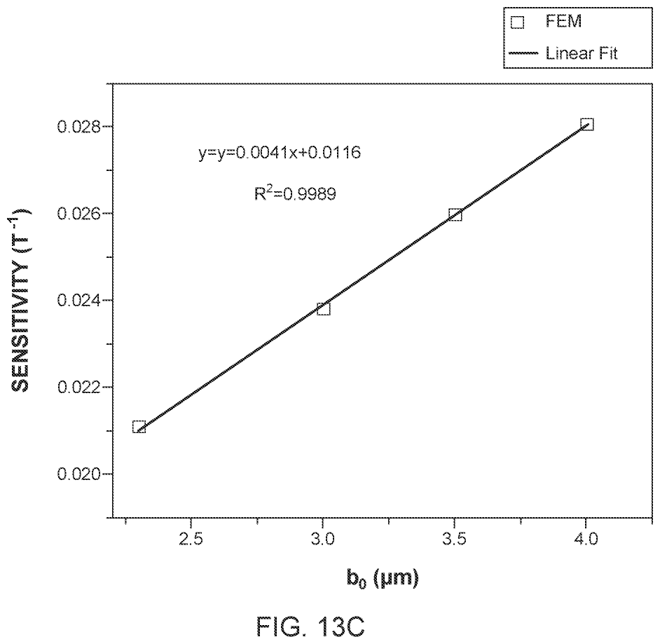

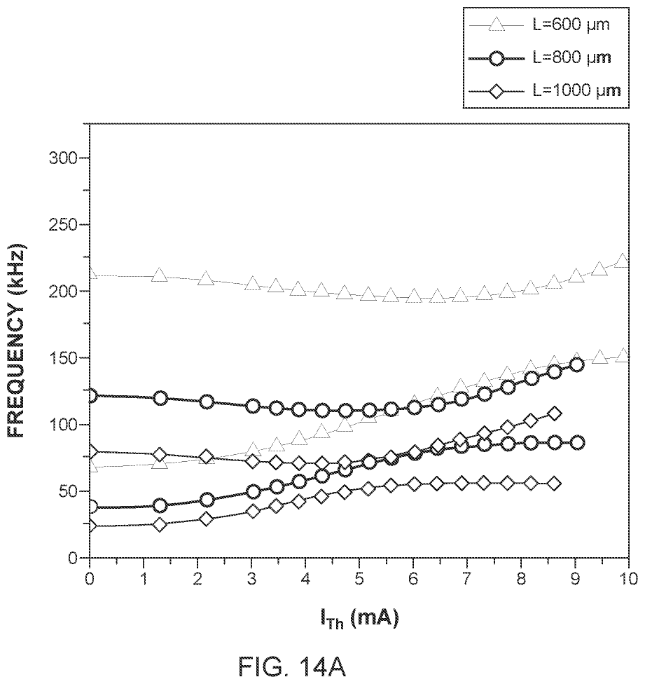

Next, the influence of the structural parameters of the micro-beam 110 on the sensitivity S of the micro-sensor 100 is investigated. The structural parameters include one or more of the initial rise of the beam 110 relative to the reference (straight beam level 116), its thickness, and the length of the beam for the first two symmetric natural frequencies. FIG. 13A shows the variation of the resonant frequencies f₁ and f₃ as a function of the applied current I_{Th}, for micro-beams having the parameters h=1.5 μm and L=800 μm, but with a different initial rise (b₀). It can be seen that increasing the initial rise b₀, the resonance frequencies get very close to each other for the critical I_{Th}, demonstrating the veering phenomenon. Also, the sensitivity for the two frequencies changes with increasing the initial rise b₀, as shown in FIGS. 13B and 13C. As noted from these figures, the sensitivity S is inversely proportional to the initial rise b₀ for the first mode, while it is proportional to b₀ for the third mode. This means that by increasing the initial b₀, the beam's stiffness increases, and thus the frequency f₁, as observed in FIG. 13A. According to equation (1), the sensitivity S is inversely proportional to the stiffness, which explains the results in FIG. 13B. On the other hand, with an increase of the initial rise b₀, the frequency f₃ decreases and gets much closer to the frequency f₁ as a result of the smaller linear mode coupling in this case. As equation (1) shows, the sensitivity S is proportional to Δf/f₀, which explains the results in FIG. 13C.

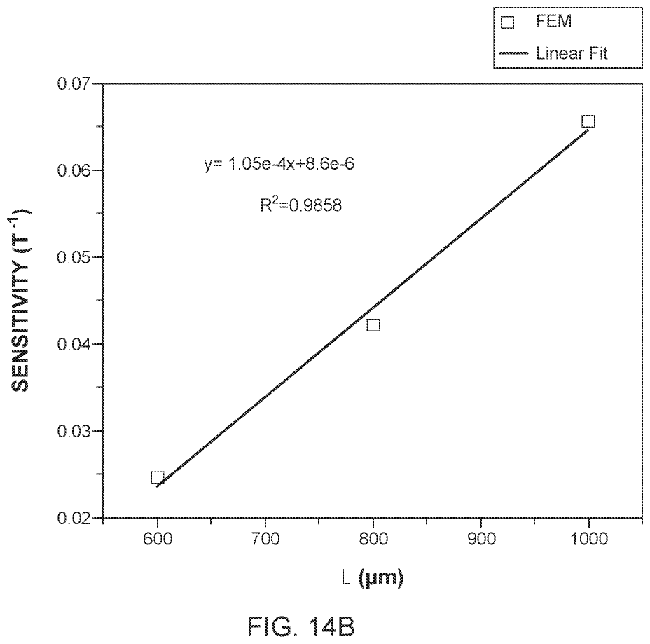

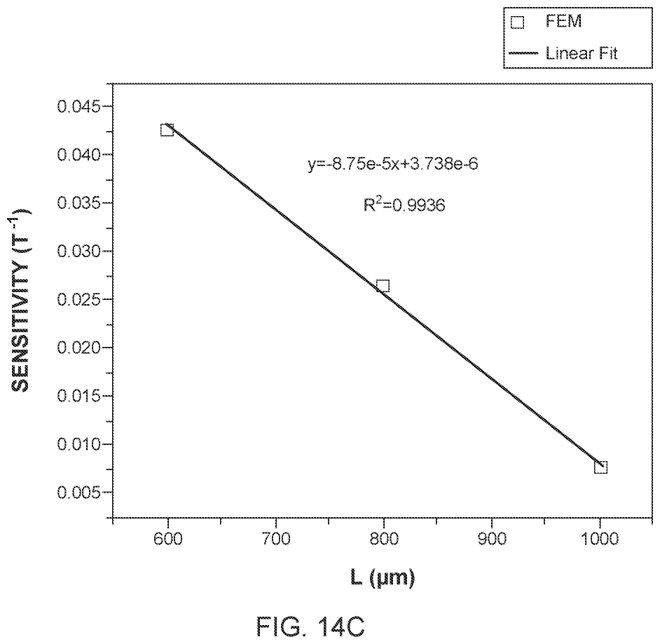

The effect of varying the length L of the micro-beam 110 on the first two symmetric frequencies is illustrated in FIG. 14A. As noted from the figure, decreasing the length L shifts the position of the veering zone from low to high values of I_{Th}. In addition, it is observed that the frequencies f₁ and f₃ become closer for a longer beam where the veering phenomenon is strongly activated. Thus, increasing the length L results in the decrease of the stiffness of the micro-beam, and thus increases its sensitivity for f₁, as illustrated in FIG. 14B. As shown in FIG. 14C, the sensitivity for the third mode is inversely proportional to the length L, i.e., it decreases with the increase in the beam's length.

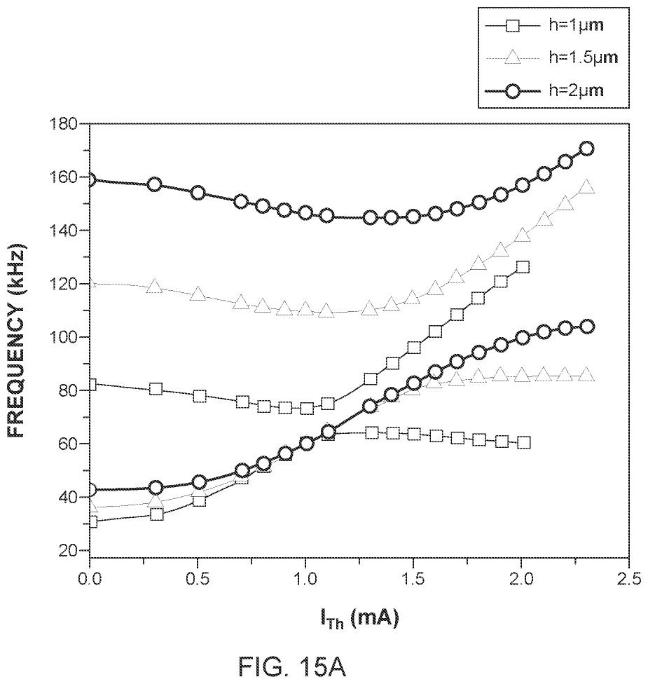

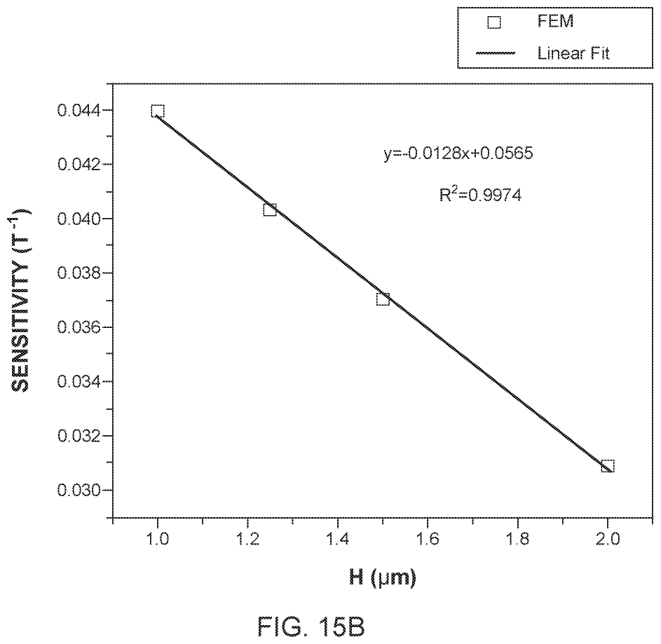

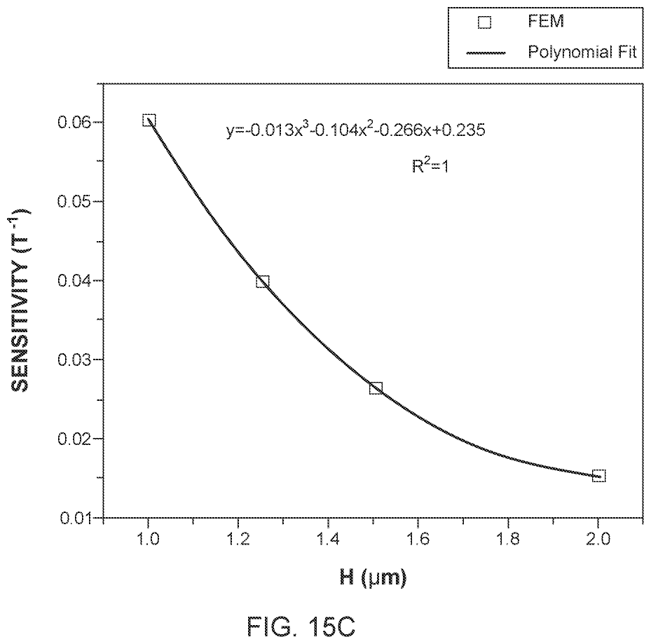

The effect of changing the micro-beam's thickness h on the first two symmetric resonant frequencies is shown in FIG. 15A. It can be seen that by increasing the thickness h, the position of the veering zone shifts from low to high values of the applied current I_{Th}. This means that increasing the thickness h strengthens the veering zone. Thus, a thicker beam means a stiffer beam, and therefore according to equation (1), the sensitivity of the micro-sensor decreases. FIGS. 15B and 15C show the dependence of the sensitivity for f₁ and f₃ with respect to the beam thickness h. The plots in these figures show that for both modes, increasing the thickness h results in stiffening the beam and thus, decreasing the sensitivity of the sensor.

Note from the previous results that the variation of the resonance frequency for the third mode is highly sensitive on the geometrical parameters, axial loads, and actuation forces around the veering zone. For example, as shown in FIG. 15A, for a thin micro-beam (h=1 μm) with a lower input current, where the veering phenomenon is strongly activated, the variation of Δf/f₀ is higher compared to a thick micro-beam. Hence, as shown in FIG. 15C, the sensitivity at the third mode with h=1 μm is 75% higher compared to the thicker micro-beams (h=2 μm). This value is reduced to 25% for the first mode.

The above results can be used to choose the geometric parameters of the micro-beam to enhance its sensitivity. At the first mode, the sensitivity can be improved by a factor of 2 if the initial rise is reduced to half. Also, because the sensitivity is proportional to the length L, the sensitivity can be further improved by a factor of 3 if a long beam of 1000 μm is used. Reducing the thickness by half can enhance the sensitivity by 47%.

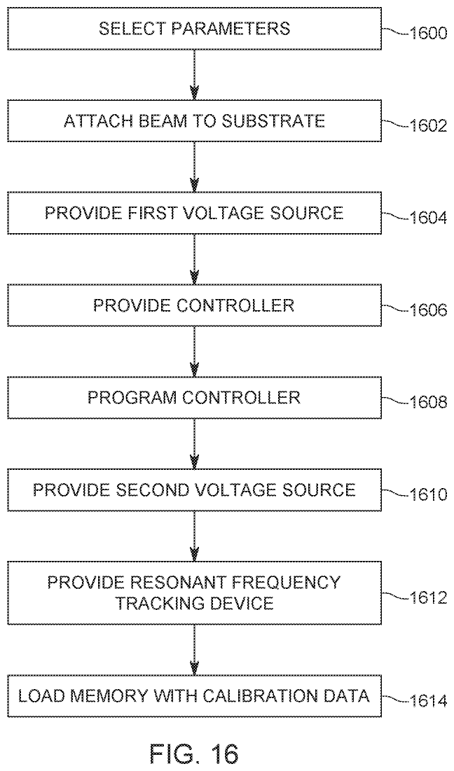

With these observations in mind, a method for manufacturing a magnetic micro-sensor is now discussed with FIG. 16. The method starts in step 1600, where the parameters (e.g., length, thickness, width, initial rise, material) of the micro-beam are selected based on the observations noted with regard to FIGS. 13A to 15C. These parameters are selected based on the results discussed above, the desired sensitivity of the sensor, and the expected magnetic field to be measured. The selection of the parameters in step 1600 ensures that the highly sensitive in-plane Lorentz-force magnetic micro-sensor exhibits the veering phenomenon between its first two symmetric vibration modes. Then, in step 1602, the micro-beam 110, having the desired geometrical properties, is attached at its ends to a substrate such that the beam is curved, i.e., it has an initial rise relative to a straight line position of the beam, as illustrated in FIG. 1. The micro-sensor demonstrates high sensitivity compared to reported magnetic sensors. The advantages of the proposed sensor are the simplicity of fabrication, excellent repeatability, and scalability. The proposed sensor can be scaled to larger (millimeter) or smaller (nanometer) sizes, depending on the aimed application, using the standard fabrication process and using the same mechanism. An actuating electrode 120 is attached to the substrate, next to the micro-beam 110. In one application, the actuating electrode and the micro-beam are parallel to each other. Then, in step 1604, a first voltage source 122 is attached to the ends of the micro-beam 110 to apply a given current. A controller 130 is connected in step 1606 to first voltage source 122 and is programmed in step 1608 to apply the given current to heat the micro-beam 110, so that its bending is controlled by the applied current. In step 1610, a second voltage source 140 is connected through an amplifier 141 to the actuating electrode. The controller may also be configured to control the voltage applied to the actuating electrode to apply the white noise to the micro-beam 110. In step 1612, a resonant frequency tracking device 150 is placed next to the micro-beam 110, to trace its resonant frequencies. The controller may be programmed to monitor the first or the third resonant frequency. In step 1614, a memory of the controller is loaded with prior data (e.g., as show in FIG. 6) that indicates a dependence of the shift in the resonance frequency with a magnetic field, and the controller can be further programed to determine the magnetic field after calculating the change in the resonance frequency, which is measured by the resonant frequency tracking device 150. In one application, the controller is configured to receive a desired sensitivity S of the micro-sensor system 200, for example, from the operator of the system. The controller may also be programmed to compare the desired sensitivity with a predetermined threshold, and select the resonant frequency to be the first resonant frequency of the micro-beam when the desired sensitivity is smaller than the threshold, and to be the third resonant frequency when the desired sensitivity is larger than the threshold. The controller may also be programmed to switch from using the first resonant frequency to the third resonance frequency based on an input from the operator of the micro-sensor, or by itself, based on the detected magnetic field.

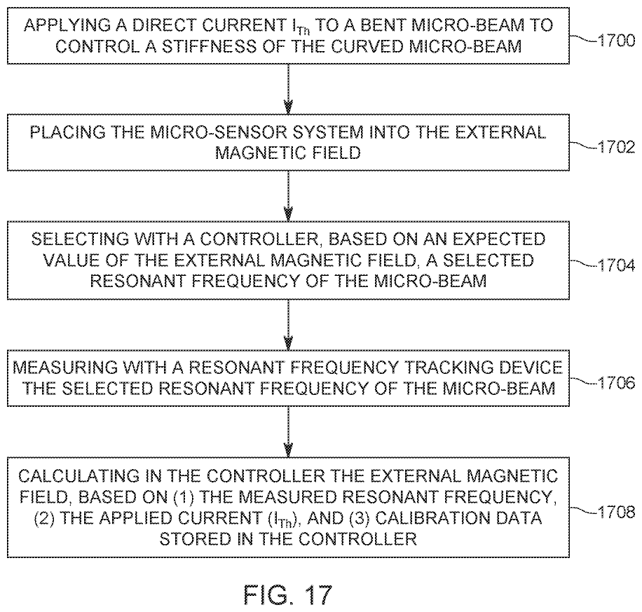

A method of measuring an external magnetic field with a micro-sensor system 200 is now discussed with regard to FIG. 17. The method includes a step 1700 of applying a direct current I_{Th} to a curved micro-beam to control a stiffness of the curved micro-beam, a step 1702 of placing the micro-sensor system into the external magnetic field, a step 1704 of selecting with a controller, based on an expected value of the external magnetic field, a selected resonant frequency of the micro-beam, a step 1706 of measuring with a resonant frequency tracking device the selected resonant frequency of the micro-beam, and a step 1708 of calculating in the controller the external magnetic field, based on (1) the measured resonant frequency, (2) the applied current (I_{Th}), and (3) calibration data stored in the controller. The calibration data is indicative of a dependency between the selected resonant frequency and the external magnetic field as shown, for example, in FIG. 6.

The selected resonant frequency is either a first resonant frequency or a third resonant frequency. The method may further include driving the micro-beam with a white noise applied by a actuating electrode. The white noise may have any frequency and any amplitude. The step of calculating includes calculating a shift in the selected resonant frequency due to the white noise applied by the actuating electrode. The method may further include mapping the shift in the selected resonant frequency to a corresponding magnetic field based on the calibration data.

The method may further include a step of receiving a desired sensitivity of the micro-sensor system, a step of comparing the desired sensitivity with a predetermined threshold, and a step of selecting the selected resonant frequency to be a first resonant frequency of the micro-beam when the desired sensitivity is smaller than the threshold, and to be a third resonant frequency when the desired sensitivity is larger than the threshold. The micro-beam is curved when no direct current (I_{Th}) is present. In one application, the sizes of the micro-beam are selected so that the micro-beam exhibits a veering zone. For this application, a first resonant frequency of the micro-beam increases while a third resonant frequency decreases up to the veering zone, and the first resonance frequency stains constant and the third resonance frequency increases after the veering zone, and the first resonant frequency never crosses the third resonant frequency.

The disclosed embodiments provide a micro-sensor that is capable to measure a magnetic field based on a change in a resonant frequency of a micro-beam that is curved. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

[1] A. Z. Hajjaj, N. Alcheikh, M. A. Hafiz, S. Ilyas, and M. I. Younis, “A scalable pressure sensor based on an electrothermally and electrostatically operated resonator,” Applied Physics Letters. vol. 111, p. 223503, 2017.
[2] N. Alcheikh, A. Z. Hajjaj, and M. I. Younis, “Highly sensitive and wide-range resonant pressure sensor based on the veering phenomenon,” Sensors and Actuators A: Physical, vol. 300, p. 111652, 2019.
[3] A. Z. Hajjaj, N. Jaber, N. Alcheikh, and M. I. Younis, “A Resonant Gas Sensor Based on Multimode Excitation of a Buckled Microbeam,” IEEE Sensors Journal, 10.1109/JSEN.2019.2950495, 2019.
[4] M. Li, S. Nitzan, and D. A. Horsley, “Frequency-modulated Lorentz force magnetometer with enhanced sensitivity via mechanical amplification,” IEEE Electron Device Letters, vol. 36, p. 62-64, 2014.
[5] M. Li, V. T. Rouf, M. J. Thompson, and D. A. Horsley, “Three-axis Lorentz-force magnetic sensor for electronic compass applications,” Journal of Microelectromechanical Systems, vol. 21, p. 1002-1010, 2012.
[6] A. Z. Hajjaj, N. Alcheikh, and M. I. Younis, “The static and dynamic behavior of MEMS arch resonators near veering and the impact of initial shapes,” International Journal of Non-Linear Mechanics, vol. 95, p. 277-286, 2017.

1. A method for measuring a magnetic field with a micro-sensor system, the method comprising:
applying a direct current (I_{Th}) to a curved micro-beam to control a stiffness of the curved micro-beam;
placing the micro-sensor system into an external magnetic field (B);
selecting with a controller, based on an expected value of the external magnetic field (B), a given resonant frequency of the micro-beam;
measuring with a resonant frequency tracking device the given resonant frequency of the micro-beam; and
calculating in the controller the external magnetic field (B), based on (1) the measured resonant frequency, (2) the applied current (I_{Th}), and (3) calibration data stored in the controller,
wherein the calibration data is indicative of a dependency between a change of the selected resonant frequency and the external magnetic field.

2. The method of claim 1, wherein the given resonant frequency is either a first resonant frequency or a third resonant frequency.

3. The method of claim 1, further comprising:
driving the micro-beam with a white noise applied by an actuating electrode.

4. The method of claim 3, wherein the step of calculating comprises:
calculating the change in the given resonant frequency due to the white noise applied by the actuating electrode.

5. The method of claim 4, further comprising:
mapping the change in the selected resonant frequency to a corresponding magnetic field based on the calibration data.

6. The method of claim 1, further comprising:
receiving a desired sensitivity of the micro-sensor system;
comparing the desired sensitivity with a predetermined threshold; and
selecting the given resonant frequency to be a first resonant frequency of the micro-beam when the desired sensitivity is smaller than the threshold, and to be a third resonant frequency when the desired sensitivity is larger than the threshold.

7. The method of claim 1, wherein the micro-beam is curved when no direct current (I_{Th}) is present.

8. The method of claim 1, wherein sizes of the micro-beam are selected so that the micro-beam exhibits a veering zone.

9. The method of claim 8, wherein a first resonant frequency of the micro-beam increases while a third resonant frequency decreases up to the veering zone, and the first resonance frequency stays substantially constant and the third resonance frequency increases after the veering zone, and the first resonant frequency never crosses the third resonant frequency.

10. A micro-sensor system for measuring an external magnetic field, the micro-sensor system comprising:
a micro-beam that is clamped at each end to corresponding first and second pads, wherein the micro-beam is curved;
a first voltage source configured to apply a direct current (I_{Th}) to the curved micro-beam to control a stiffness of the curved micro-beam;
a controller configured to control the first voltage source, and based on an expected value of the external magnetic field, to select a given resonant frequency of the micro-beam to be monitored; and
a resonant frequency tracking device configured to measure the given resonant frequency of the micro-beam,
wherein the controller calculates the external magnetic field (B), based on (1) the measured resonant frequency, (2) the applied current (I_{Th}), and (3) calibration data stored in the controller,
wherein the calibration data is indicative of a dependency between a change of the given resonant frequency and the external magnetic field.

11. The micro-sensor system of claim 10, wherein the given resonant frequency is either a first resonant frequency or a third resonant frequency.

12. The micro-sensor system of claim 10, further comprising:
an actuating electrode placed next to the micro-beam; and
a second voltage source driving the micro-beam with a white noise applied by the actuating electrode.

13. The micro-sensor system of claim 12, wherein the controller is further configured to,
calculate the change in the given resonant frequency due to the white noise applied by the actuating electrode.

14. The micro-sensor system of claim 13, wherein the controller is further configured to:
map the change in the given resonant frequency to a corresponding magnetic field based on the calibration data.

15. The micro-sensor system of claim 10, wherein the controller is configured to receive a desired sensitivity of the micro-sensor system, compare the desired sensitivity with a predetermined threshold, and select the given resonant frequency to be a first resonant frequency of the micro-beam when the desired sensitivity is smaller than the threshold, and to be a third resonant frequency when the desired sensitivity is larger than the threshold.

16. The micro-sensor system of claim 10, wherein sizes of the micro-beam are selected so that the micro-beam exhibits a veering zone.

17. The micro-sensor system of claim 16, wherein a first resonant frequency of the micro-beam increases while a third resonant frequency decreases up to the veering zone, and the first resonance frequency stays substantially constant and the third resonance frequency increases after the veering zone, and the first resonant frequency never crosses the third resonant frequency.

18. A method of manufacturing a micro-sensor system that measures an external magnetic field, the method comprising:
selecting geometrical characteristics of a micro-beam so that the micro-beam exhibits a veering zone;
attaching both ends of the micro-beam to corresponding pads so that the micro-beam is curved;
providing a first voltage source to supply a current to the micro-beam to control a stiffness of the micro-beam;
providing a controller for controlling the first voltage source and selecting a given resonance frequency;
providing a second voltage source for driving a actuating electrode with white noise;
providing a resonant frequency tracking device for measuring a resonant frequency of the micro-beam; and
loading calibration data into the controller,
wherein the calibration data is indicative of a dependency between a change of the given resonant frequency and the external magnetic field.

19. The method of claim 18, further comprising:
programming the controller to control the second voltage source to apply the white noise to the micro-beam, and also to calculate the change in the given resonance frequency.

20. The method of claim 19, further comprising:
programming the controller to map the change in the given resonance frequency to a value the external magnetic field.
